(19) United States
(12) Patent Application Publication
(10) Pub. No.: US 2012/0207944 A1
(43) Pub. Date: Aug. 16, 2012

(54) FABRICATION AND SELECTIVE PATTERNING OF THIN FILMS USING ION BEAM-ENHANCED ATOMIC AND MOLECULAR LAYER DEPOSITION

(76) Inventors: Dudley Sean Finch, Ashland, OR (US); Steven McClellan George, Boulder, CO (US)

(21) Appl. No.: 13/212,143

(22) Filed: Aug. 17, 2011

Related U.S. Application Data
(60) Provisional application No. 61/374,427, filed on Aug. 17, 2010.

(51) Int. Cl. C23C 14/04; C23C 14/48

(52) U.S. Cl. 427/526; 427/523

(57) ABSTRACT

Generally, the present invention relates to patterning techniques for creating nanoscale features on a substrate. The invention offers an improved method over traditional e-beam or photolithographic techniques and uses atomic layer deposition (ALD) chemistries and a source of high-energy ions. These either as focused or a flood of ions facilitate ALD deposition by providing additional energy to the reaction or, more significantly, can form part of the final chemical structure of the ALD coating.

Additional embodiments include using ion beam-assisted ALD to deposit a seed layer for subsequent thermal ALD processes, and ion beam-assisted molecular layer deposition chemistries (MLD) for direct patterning of organic and/or inorganic long-chain macromolecules (e.g., polymers, proteins, peptides and polysaccharides). A further embodiment combines both ALD and MLD methods to allow fabrication of unique hybrid metal, semiconductor or dielectric ALD and organic or inorganic MLD films.

This document is a non-provisional application following the provisional patent filed on Aug. 17, 2010 with an assigned Application Number: 61/374,427.

### 1. FIELD OF THE INVENTION

This invention generally relates to techniques for creating nanoscale features or patterns on a substrate and is intended for, but not limited to, use in the fabrication of semiconductor or micro electromechanical systems (MEMS) devices. More specifically, the present invention offers an improved method over traditional e-beam or photolithographic techniques employed by these industries to allow direct patterning on a substrate using a combination of atomic layer deposition (ALD) chemistries and an accelerated ion beam. The invention could also be extended to the combination of molecular layer deposition (MLD) and an accelerated ion beam.

In this invention, an ion beam is accelerated using an extractor to give energies in the range of several hundred to several thousand volts and can be either a focused or a flood source of ions. The use of a focused ion source facilitates a maskless process suitable for small volume production. The use of a flood ion source in combination with a die-level shadow mask facilitates wafer level processing and is therefore more suitable to mass production.

Specific high-energy ions, such as argon (Ar⁺), helium (He⁺) and xenon (Xe⁺), can be used to facilitate ALD chemical reactions by providing extra energy to the ion collision. Or, more significantly, specific ions can themselves become chemical participants; for example, using oxygen (O⁺), hydrogen (H⁺) or hydroxyl (OH⁻) ions to enhance the chemical reactions associated with the deposition of ALD or MLD thin films.

By utilizing ALD and MLD chemistries, a wide range of materials is available for the fabrication of thin films used for conductors, semiconductors, polymers and dielectrics. A combination of these materials in the form of multilayers or alloys is also possible. Because of the self-terminating nature of ALD and MLD chemistries, direct control of layer thickness can be achieved by using a finite number of ALD or MLD cycles.

In addition to direct patterning using a wide range of chemistries, it is possible to control the final chemistry of the surface, allowing the fabrication of site-specific seed layers with preferred chemistry and functionality. Once formed, the seed layers can act as nucleation sites for subsequent ex situ film growth using thermally-assisted ALD or MLD reactions.

### 2. BACKGROUND OF THE INVENTION

Traditional methods for creating nanoscale features or patterns on silicon substrates include photo- and electron-beam lithography. Lithographic processes are used to selectively remove parts of a deposited thin film or to remove material from the bulk of a substrate.

In the case of photolithography, light is used to project a pattern from a photomask that can be stepped die-by-die across a whole wafer, exposing a light-sensitive photoresist that has been previously spun or sprayed onto the surface of the substrate. Following exposure, the wafer undergoes a development process that leaves a positive or negative layer of photoresist that is a copy of the features on the stepped photomask. Once completed, the patterned photoresist allows wet or dry etching of the substrate in areas not protected by the residual photoresist. When the photoresist is no longer needed, it can be removed chemically using a solvent or with an oxygen plasma, the latter resulting in ashing of the photoresist. The resolution that can be achieved using photolithography is related to the wavelength of light used to expose the photoresist, with features less than 30 nm obtained with immersion lithography,¹ sub-20 nm features with extreme ultraviolet lithography² and X-ray lithography.³

The limitations of photomasks, such as misalignment issues and lack of process flexibility, have led to the development of maskless processes. Probably the most widely adopted maskless process is electron-beam (e-beam) lithography, which involves the scanning of a beam of electrons across the surface of the substrate that has been previously coated with a thin (1 to 10 micrometer) electron-sensitive resist. By incorporating a device for blanking the e-beam, it is possible to selectively expose the resist to the electron beam. Following exposure, the resist is developed so that either the exposed or unexposed part of it is removed. In a similar manner to the use of a photoresist, areas of the substrate not protected by the resist can be metalized, dry- or wet-etched to form nanoscale features with a current practical feature size limit of around 20 nm. The major disadvantage of electron beam lithography is the time it takes to expose an entire silicon wafer, hence other maskless lithographic techniques have evolved; for example, the use of a programmable reflective photomask and direct laser writing. Other issues, such as the generation of a large number of secondary electrons that broaden the exposed area of the resist, can also reduce the minimum resolution attainable.⁴

More recently, direct-patterning e-beam techniques using self-assembled monolayers (SAMs) have been demonstrated, opening up alternative approaches to the traditional use of photo and electron resists. An example of a directly-patterned SAM is nitrobiphenyl-thiol, where exposure of the monolayer to the e-beam reduces a terminal nitrate group to yield an amine group for subsequent selective attachment. The use of SAMs, however, is not compatible with typical semiconductor processing technology.

Other maskless and resistless direct-patterning techniques for creating sub-micrometer features include nanoimprint lithography.⁵ This process is simple with low cost, high throughput and high resolution. Patterns are created by mechanically deforming an imprint resist that is either a monomer or polymer cured by heat or UV light during imprinting. The technique is currently limited in terms of overlay errors and the potential for defects because of the direct contact involved. Another maskless and direct-patterning technique for creating sub-micrometer features is dip pen lithography.⁶ This approach enables direct deposition of nanoscale materials onto a substrate, using for example the tip of an atomic-force or scanning-probe microscope. Massively parallel patterning has been demonstrated by using two-dimensional arrays of 55,000 tips. The technique is currently limited to features around 100 nm and is not directly suited to deposition in via, hole or trench structures.

Focused ion beams composed of gallium (Ga⁺) and more recently helium (He⁺) ions⁷ have been used for nanoscale patterning. In the case of Ga⁺ ions, growing nanoscale structures on a substrate typically involves injecting a complex organometallic gas into the Ga⁺ ion beam. Alternatively, the high mass and energy of the Ga⁺ ions can be used to mill nanoscale patterns etched in a substrate. In either case, resultant Ga⁺ ion implantation makes the process unsuitable for semiconductor or MEMS device applications and, like e-beam lithographic techniques, is serial in nature and again not suited to mass production. In the case of using He⁺, the low mass of the ion makes the etch rate very slow for milling. Since only ˜10% of the primary ions form secondary ions, there are no type II secondary (backscattered) electrons generated from a He ion beam. This allows an ion beam to be created with a very small focused spot size to give high resolution imaging (˜0.3 nm). In addition, there is the possibility for high-resolution patterning with He ions using the energy of the ion beam (up to 30 kV) to facilitate ALD chemistry. Because the He⁺ ions are inert, the ions themselves cannot participate in the reactions directly. Both Ga⁺ and He⁺ focused ion beams point toward the role of ions in nanoscale patterning but suffer in principle from the same serial nature of the process. The time required to expose large areas of a wafer make focused ion beams impractical for mass fabrication.

This invention specifically relates to the use of ion beams in combination with atomic layer deposition (ALD) and molecular layer deposition (MLD) techniques for nanoscale patterning of thin films. ALD and MLD techniques are used to obtain atomic layer-controlled and conformal growth of adherent thin films by employing sequential, self-limiting surface chemical reactions.⁸ ALD and MLD offer exquisite control over growth in the vertical dimension but very little has been accomplished to selectively pattern ALD or MLD on the horizontal plane. Some work has demonstrated patterning using selective-area ALD, based on masking with self-assembled monolayers (SAM).⁹ However, the deposition of the SAM is often incompatible with gas phase ALD techniques, and the subsequent removal of the SAM can be problematic.

This invention offers an improved method for selective deposition on a substrate using ALD enhanced by a high-energy (several hundred to several thousand volts) ion beam. The ion beam can be either focused or collimated. Ions such as argon (Ar⁺), gallium (Ga⁺), helium (He⁺) or xenon (Xe⁺) can facilitate selective ALD by providing extra energy to the ALD reactions. Alternatively and more significantly, ions such as oxygen (O⁺), hydrogen (H⁺) or hydroxyl (OH⁻) can also be chemical participants in the reaction, in addition to providing extra energy.

Inducement of the ALD surface reactions occurs because the ion energy is typically several hundred to several thousand volts. These kinetic energies are able to induce chemical reactions that have activation barriers typically less than chemical bond energies of ˜2-4 eV. Selective deposition of chemical vapor-deposited (CVD) thin films has been demonstrated using focused Ga⁺ ion beams to induce CVD reactions.^{10, 11} Again though, due to the high mass and energy of the ion beam, Ga⁺ ions implanted into the deposited CVD film make such an approach unfavorable for ion beam-assisted ALD. The energetic Ga⁺ ions can also remove and alter surface properties, which may affect the subsequent ALD or MLD surface reactions. Consequently, this invention proposes the use of high energy/low mass ions such as O⁺, H⁺ or OH⁻ that can, in addition to providing energy to the reactions, actively participate in the ALD and MLD reactions.

Ion beam-assisted ALD may be effective for the deposition of various materials including dielectrics, semiconductors and metals. Some of the best candidates for ion beam-assisted ALD are thermal ALD systems that are known to be challenging, such as copper (Cu) ALD and tantalum nitride (TaN) ALD. Using challenging thermal ALD systems serves to provide high contrast between the ion beam-assisted ALD areas and the surrounding substrate. Examples of challenging systems include Cu (hexafluoroacetylacetonate [hfac])₂ and H⁺ ion beams for Cu ALD, and t-Butylamino (diethylamino) tantalum (TBTDET) and H⁺ ion beams for TaN ALD.

Ion beam-assisted ALD could also be used to deposit a seed layer on the surface that would facilitate subsequent thermally-assisted ALD processes. For example, platinum (Pt) ALD, using trimethyl (methylcyclopentadienyl) platinum (IV) [MeCpPt(Me)₃], does not nucleate easily on various oxide surfaces such as silicon dioxide (SiO₂).¹² However, plasma Pt ALD nucleates almost immediately using MeCpPt(Me)₃ and an O₂ plasma. Recent work has shown that thermal Pt ALD will occur easily on a seed layer that is deposited using plasma Pt ALD.¹² A similar procedure could be developed with ion beam-assisted ALD using MeCpPt(Me)₃ and an O⁺ ion beam to establish a Pt ALD seed layer on the substrate. Following the deposition of this seed layer, thermal Pt ALD could be utilized to continue the growth of the Pt ALD film.

### 3. SUMMARY OF THE INVENTION

This invention meets the need for a process to make a selectively patternable film with atomically controlled thickness that is compatible with semiconductor and MEMS fabrication processes. The invention uses a combination of high energy (several hundred to several thousand volts) ions and atomic or molecular layer deposition (ALD/MLD) chemistries. Energetic ions such as argon (Ar⁺), helium (He⁺) or xenon (Xe⁺) can be used to provide energy to the ALD or MLD reaction. Alternatively, high energy/low mass ions such as oxygen (O⁺), hydrogen (H⁺) or hydroxyl (OH⁻) can, besides providing energy to the reaction, also participate chemically in the reaction. In a final embodiment, this approach could be used to generate seed layers on a substrate for subsequent thermally-assisted ALD growth of thin films.

### 4. BRIEF DESCRIPTION OF THE DRAWINGS

FIG. 1 is a schematic of a typical AB addition sequence for the fabrication of ALD thin films.

FIG. 2 is a scanning electron micrograph showing a cross-sectional view of the conformality achievable for thermally-assisted ALD alumina-filled trenches in a silicon wafer.

FIG. 3 is a schematic of an ion beam-assisted ALD reaction scheme using a focused ion source.

FIG. 4 is a schematic of an ion beam-assisted ALD reaction scheme in the case of a flood ion source with a die-level shadow mask.

FIG. 5 is a schematic where nanopatterned seed layers previously produced by the ion beam-assisted ALD reaction scheme are used for ex situ thermal growth of ALD films.

### 5. DETAILED DESCRIPTION OF THE INVENTION

The invention, described in detail below with respect to its preferred embodiment, can be used for direct patterning of a substrate such as those used in semiconductor or MEMS processes. The invention utilizes a combination of an ion beam with atomic or molecular layer deposition (ALD or MLD).

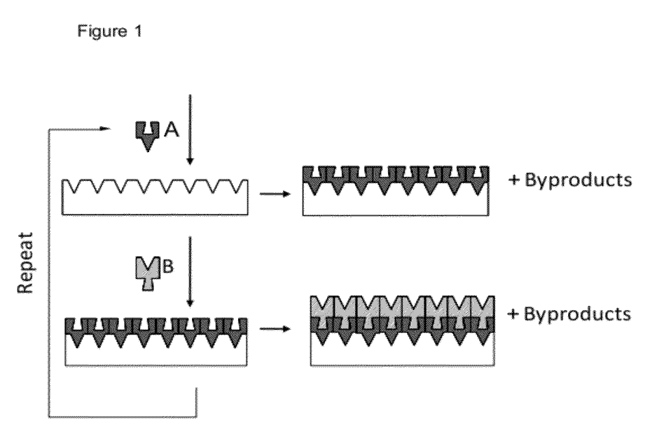

FIG. 1 illustrates the basic principles of ALD, whereby a precursor gas phase molecule A is introduced and chemically reacts with a surface.⁸ Following completion of the reaction, a second precursor gas phase molecule B is introduced and reacts chemically with the surface resulting from the A reaction to form a new surface species. This resultant surface is now ready for another A reaction. By repeating this cycle a controlled number of times, the film can be built up atomic layer-by-atomic layer to obtain the desired film thickness.

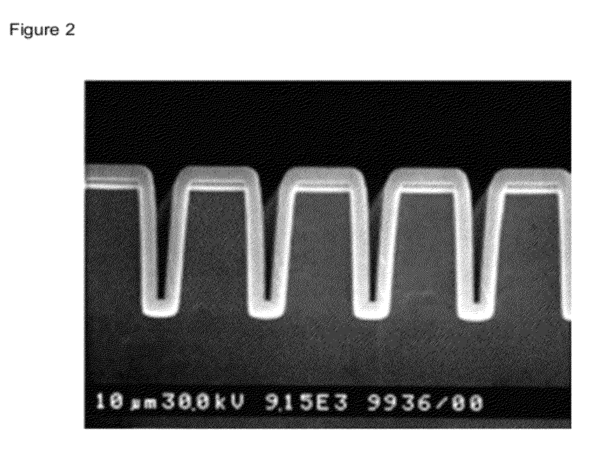

FIG. 2 shows an example of thermally-assisted ALD alumina-coated trenches in a silicon wafer, illustrating the conformality achieved by using ALD processes.¹³

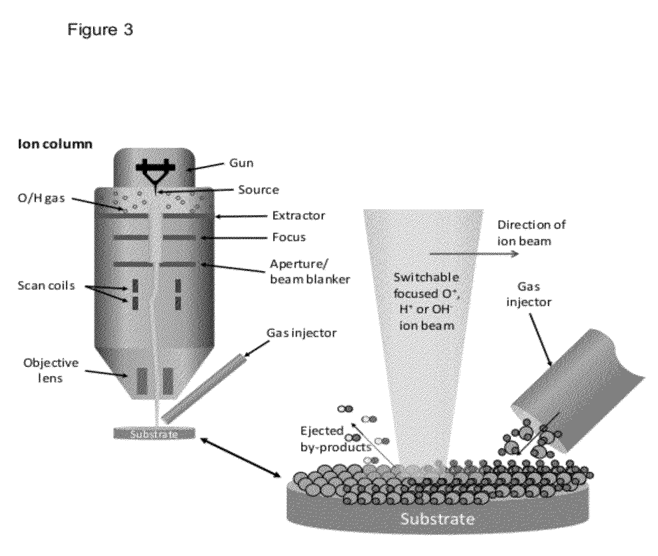

FIG. 3 depicts one embodiment of this invention whereby direct patterning can be accomplished using a focused ion beam. The method for generating the focused ion beam is shown schematically on the left side of the figure where the ions are generated by a gun and source, followed by high voltage extraction into a column held under high vacuum. The ion beam is translated using scan coils and focused onto a substrate using an objective lens. In one embodiment the focused ion beam consists of high energy argon (Ar⁺), helium (He⁺) or xenon (Xe⁺) ions that are directed at a substrate whilst individual A or B precursor gas phases are introduced into the vicinity of the ion beam by a gas injector. The ions in this instance provide the necessary energy to facilitate the A or B reactions. The reactions occur only where the ion beam, substrate and gas phase meet, keeping the surrounding area free of ALD deposition. In an alternative embodiment following the A or B reactions, high energy/low mass oxygen (O⁺), hydrogen (H⁺) or hydroxyl (OH⁻) ions can be introduced and used to form the complete two-part ALD surface reaction process. By repeatedly cycling, this two-step process makes it possible to grow patterned structures with atomic precision.

Within this embodiment there are two different operational procedures, which of themselves will lead to different outcomes. In the first procedure as illustrated in FIG. 3, the ion beam is present simultaneously with the flowing ALD gases. In this embodiment, the ALD reactions occur when the ion beam induces the reaction on the surface. The ALD surface reactions could be induced well below temperatures where thermal ALD reactions normally occur, and would occur only at surface positions where the ALD reactants are exposed to the ion beam. In the second procedure (not illustrated), the initial ALD reaction would be allowed to occur without the ion beam present, with the resulting surface species subsequently changed or modified by exposure to the ion beam.

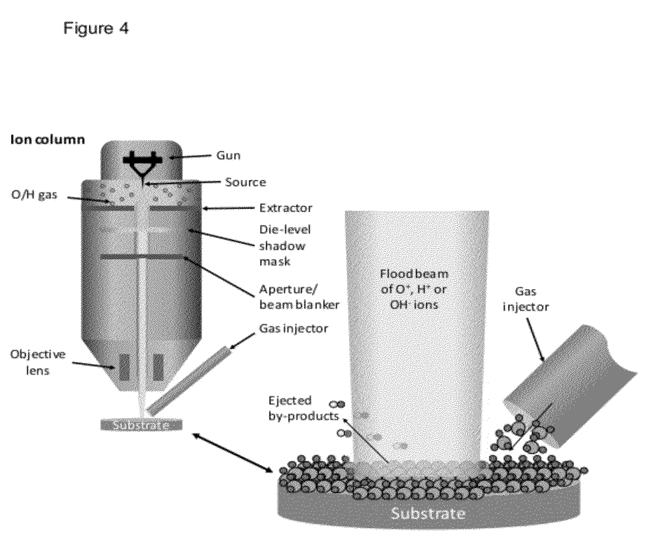

The approach as outlined in FIG. 3 is excellent for small volume production and may be applicable to targeting nanoscale-patterned ALD features. An example of this would be to fill a nanometer-sized via or hole with specific ALD-derived materials. However, as with e-beam lithography, this approach is serial in nature and hence a time-consuming process not suited to large area deposition. In this regard, an alternative approach is shown in FIG. 4. To pattern the ALD film over a large area, a die-level shadow mask is introduced between the substrate and the ion source. The mask itself has been previously patterned using a standard lithographic technique so that it allows ions to pass through apertures that selectively expose the underlying substrate in the presence of the gas phase ALD precursors.

As shown in FIG. 4, the embodiment includes an objective lens beneath the die-level shadow mask so that a four or more times reduction in mask feature size can be obtained, making smaller nanoscale-patterned features attainable. The ion beam in this case is collimated at the level of a single die in a direction perpendicular to the substrate. As shown, the ions pass through the shadow mask, the aperture/beam blanker and an objective lens before they interact with the ALD precursor gases arriving through a gas injector onto the substrate.

In an alternative embodiment (not illustrated), the die-level shadow mask could be held at a fixed distance above the substrate using a gas-bearing cushion whose components could also be part of the carrier gas for the ALD precursors. By using a shadow mask close to the surface of the substrate, this technique offers a unique geometry in which the ALD precursors are introduced beneath the die-level shadow mask, thereby creating a “flow channel” between the substrate and the shadow mask that localizes the ALD precursors and increases their efficiency. The collimation of the ion beam in this configuration would facilitate the filling of a trench or a via from the bottom up with minimal ion beam-assisted ALD deposited on the sidewalls, which is advantageous for certain semiconductor device structures such as gate oxides.

Using either approach, exposing a whole wafer is accomplished by moving the wafer in a step-wise fashion under the ion beam that can be blanked out between each step-wise movement. This is similar in principle to the use of a stepper for exposing individual die in traditional semiconductor fabrication.

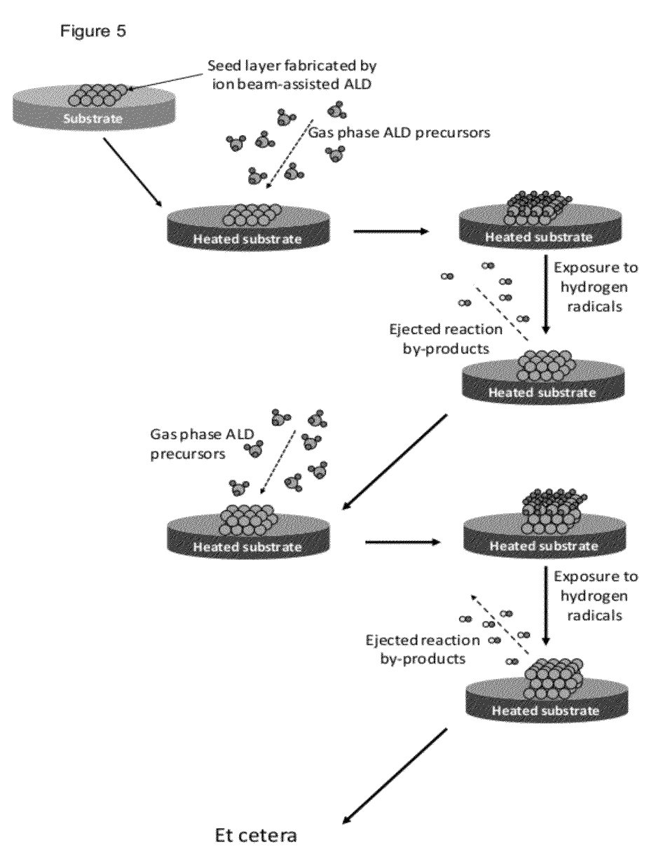

With reference to FIG. 5, ion beam-assisted ALD could also be used to deposit a seed layer on the surface of the substrate (shown in the top left of FIG. 5), after which the substrate could be removed and exposed to subsequent thermally-assisted ALD processes. One example to demonstrate this embodiment is platinum (Pt) ALD. The precursor trimethyl (methylcyclopentadienyl) platinum (IV) [MeCpPt(Me)₃] does not nucleate easily on various oxide surfaces such as silicon dioxide (SiO₂).¹² However, Pt ALD nucleates almost immediately using MeCpPt(Me)₃ and an O₂ plasma. It has also been shown that thermal Pt ALD will occur easily on a seed layer that is deposited using plasma Pt ALD.¹² Therefore, this embodiment would use a similar two-step procedure with MeCpPt(Me)₃ and an O⁺ ion beam applied separately and sequentially to establish a Pt ALD seed layer on the substrate. Following the deposition of this seed layer, thermally-assisted Pt ALD could be utilized to continue the growth of the Pt ALD film. This procedure would allow the film to be grown simultaneously over the whole wafer, making the process suitable for mass wafer production.

### 6. REFERENCES

1. Aaron Hand, Semiconductor International, April (2006).

2. Omkaram Nalamasu, May Cheng, Allen G. Timko, Victor Pol, Elsa Reichmanis and Larry F. Thompson, Journal of Photopolymer Science and Technology 4, Number 3, 299-318 (1991).

3. Y. Vladimirsky, Lithography in Vacuum Ultraviolet Spectroscopy II, Eds. J. A. Samson and D. L. Ederer, Ch 10 pp 205-223, Academic Press (1998).

4. G. Urban, Sens. Actuators 74, 219 (1999).

5. S. Y. Chou et al., Science 272, 85 (1996).

6. R. D. Piner, J. Zhu, F. Xu, S. Hong and C. A. Mirkin, Dip Pen nanolithography, Science 283, 661-663 (1999).

7. D.C. Bell, M. G. Lemme, L. A. Stern, J. R. Williams and C. M. Marcus, Nanotechnology 20 (2009).

8. S. M. George, Chemical Reviews 110, 111 (2010).

9. R. Chen, H. Kim, P. C. McIntyre, D. W. Porter and S. F. Bent, Applied Physics Letters 86, 191910 (2005).

10. S. Reyntjens and R. Puers, Journal of Micromechanics and Microengineering. 11, 287 (2001).

11. G. M. Shedd, H. Lezec, A. D. Dubner and J. Meingailis, Applied Physics Letters 49, 1584 (1986).

12. H. C. M. Knoops, A. J. M. Mackus, M. E. Donders, M. C. M. van de Sanden, P. H. L. Notten and W. M. M. Kessels, Electrochemical and Solid State Letters 12, G34 (2009).

13. M. Ritala et al., Chem. Vap. Deposition 5, 7 (1999).

What is claimed is:

1. A method for depositing atomic or molecular layers on a substrate using a combination of an energetic ion beam and self-limiting atomic or molecular layer deposition chemistry, wherein the thickness of said atomic- or molecular-deposited layer is determined by the number of self-limiting cycles.

2. The method according to claim 1, wherein the said energetic ion beam provides the necessary energy to assist in the formation of the deposited atomic or molecular layers.

3. The method according to claim 1, wherein the said energetic ion beam provides the ion moieties that, when combined chemically with atomic or molecular deposition precursors, form the deposited atomic or molecular layers.

4. The method according to claim 1, whereby the energetic ion beam floods the entire surface of the substrate, enabling uniform atomic or molecular deposition to occur.

5. The method according to claim 1, whereby a shadow mask is placed between the energetic ion beam and the substrate, allowing selective patterning of the deposited layer on a substrate at the point where the unmasked portion of the energetic ion beam and the atomic or molecular deposition chemistry react.

6. The method according to claim 1, whereby the energetic ion beam is focused, which enables direct writing of the atomic- or molecular-deposited layers onto the substrate.

7. The method according to claim 1, whereby the said atomic- or molecular-deposited layers act as seed layers for subsequent layer growth by alternate means such as thermally-assisted atomic or molecular layer deposition.
